(19) United States
(12) Patent Application Publication
(10) Pub. No.: US 2007/0291287 A1
(43) Pub. Date: Dec. 20, 2007

(54) CUSTOMER-BASED VISUAL PRINTER COLOR-TO-MONITOR COLOR MATCHING

(75) Inventors: Trevor J. Snyder, Newberg, OR (US); Stephen M. Kroon, Sherwood, OR (US); Paul J. Woodward, West Linn, OR (US)

Correspondence Address: MARGER JOHNSON & MCCOLLOM, P.C., 210 SW MORRISON STREET, SUITE 400, PORTLAND, OR, 97204, US

(73) Assignee: XEROX CORPORATION, Stamford, CT (US)

(21) Appl. No.: 11/424,182

(22) Filed: Jun. 14, 2006

(51) Int. Cl. G03F 3/08

(52) U.S. Cl. 358/1.9; 358/518; 358/3.01

(57) ABSTRACT

A method for printer to monitor color matching includes displaying a target color pattern corresponding to a source color pattern and printing a plurality of reference color patterns, each reference color pattern corresponding to a color corrected source color pattern. The method includes comparing the reference and target color patterns and determining whether there is a match according to a user-defined criteria. A system includes a display device to display a source color pattern represented in a first color space in a second color space; a printer to map first color space values of the source color pattern to third color space values associated with the printer; color correction transforms to map the third color space values associated with the printer to another set of color space values; and a printer driver to configure color settings according to the selected color correction transform and a selected print mode.

### BACKGROUND

Color printer customers, such as graphic and printing industries users, photographers, etc., have different needs and applications. While print quality on a printer may be satisfactory or considered good for one set of customers having a particular application, the print quality on the same printer may be inadequate or considered poor for another set of customers having a different application.

An important component of print quality is producing prints that match images displayed on a monitor. However, color matching between display monitors and printers remains a challenge today. Color distortions occur because different devices have different color gamuts. This is due to a number of factors including the monitor technology and age, the printer imaging technology, and dyes or pigments that are used. A printer with a smaller color gamut than a monitor cannot reproduce all of the colors that can be shown on the monitor. Similarly, high quality printers having a larger gamut may be able to reproduce a number of colors outside the gamut of an average display monitor.

Color matching solutions continue to be a source of frustration for users because conventional solutions typically require a trial-and-error process necessitating various corrections, reading a user manual, and even making service calls to the manufacturer. Some conventional solutions even require specialized and expensive equipment that measure and analyze the outputs of the monitor and the printer. Some solutions also require a deep understanding of color science which may be acceptable for a graphic designer, but not useful at all for the average customer.

Thus, to meet the requirements of different customers and to reduce the need for special equipment and special knowledge, there is a need for a simple and intuitive process to calibrate the colors between the user's hardware such as between a monitor and a printer.

### SUMMARY

In one embodiment, a method for printer color to monitor color matching includes displaying a target color pattern corresponding to a source color pattern and printing a plurality of reference color patterns, each of the reference color pattern corresponding to a color corrected source color pattern. The method further includes visually comparing the plurality of reference color patterns with the target color pattern and determining whether one of the plurality of reference color patterns matches the target color pattern according to a user-defined criteria.

In another embodiment, a system for matching printer color to monitor color includes a display device to display a source color pattern in a second color space, wherein the source color pattern is represented in a first color space; and a printer to map the first color space values of the source color pattern to values in a third color space associated with the printer and print a plurality of color corrected source patterns. The printer may include a plurality of print modes, each print mode corresponding to an amount of ink to be transferred to a print medium. The system further includes a plurality of color correction transforms to map the third color space values associated with the printer to another set of color space values defined by a selected one of the plurality of color correction transforms; and a printer driver to configure color settings of the printer according to the selected color correction transform and a selected print mode.

### BRIEF DESCRIPTION OF THE DRAWINGS

FIG. 1 is a block diagram of a system for matching colors displayed on a monitor to colors printed on a printer.

FIG. 2 is a flowchart illustrating one embodiment of a method for matching colors displayed on a monitor to colors printed on a printer.

### DETAILED DESCRIPTION

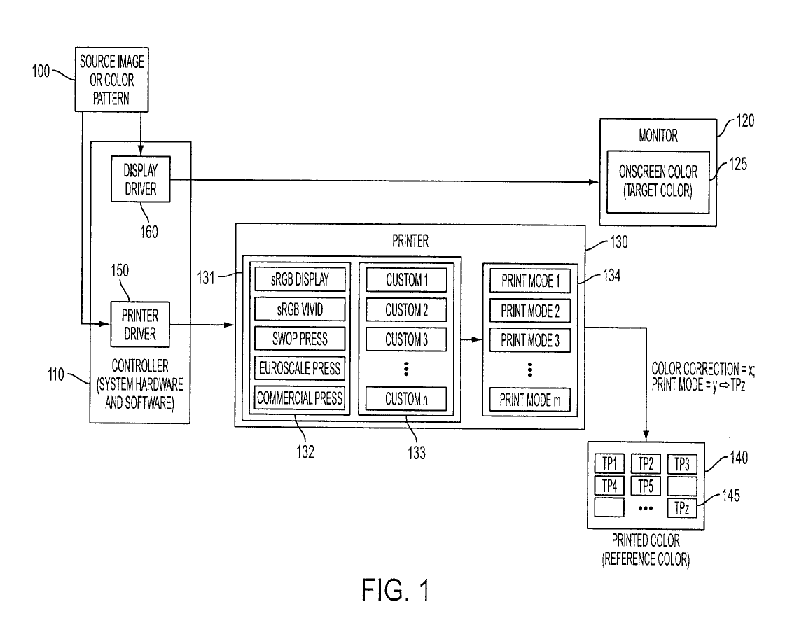

FIG. 1 is a block diagram of a system for calibrating colors displayed on a monitor to colors printed on a printer. In one embodiment, the system may include a controller 110, a display device such as a color monitor 120, and a printing device such as a color printer 130. The controller 110 may include hardware and software modules to coordinate communications with the color monitor 120 and the color printer 130. The color printer 130 may include all types of printers including, for example, laser printers and solid ink printers.

When a user initiates a process for matching printer color to monitor color, the controller 110 sends a source image or color pattern 100 to the color monitor 120 to display a color test pattern (the target color) 125. The controller 110 also requests the color printer 130 to generate and print a plurality of color test patterns (the reference colors) 145 on a printing medium 140, each reference color test pattern corresponding to a color corrected source image or color pattern.

The source image or color pattern 100 may include, for example, color bars, photographs, and blocks of colors. Preferably, the source image or color pattern 100 includes a wide range of tonal values. In one embodiment, the source image or color pattern 100 preferably includes predefined test patterns that are typically included in memory in conventional printers. In another embodiment, the source image or color pattern 100 includes images or test patterns that may be sent from or through a software application.

The source image or color pattern 100 may consist of a two-dimensional array of picture elements or pixels. Each image pixel is associated with a color space. That is, each image pixel may be represented by a set of color space values that defines, in effect, what the color of the pixel looks like. The color of each image pixel may be represented in any color space, such as RGB color space or CMYK color space. The RGB color space, commonly used by color display devices, represents pixel colors according to the relative contributions of three primary colors red, green, and blue. The CMYK color space, commonly used by color printing devices, represents colors corresponding to the relative contributions of the colorants cyan, magenta, yellow, and black.

To simplify the disclosure and understanding of the system for color matching, the source image or color pattern 100 and the color monitor 120 may be assumed to be in the RGB color spaces, while the color printer 130 may be assumed to be in the CMYK color space. These example color spaces are for illustrative purposes only and not intended to limit the scope of the claims in any way. As described above, the source image or color pattern 100 may be represented in any color space. Similarly, the color monitor 120 and the color printer 130 may utilize other color spaces.

The system preferably includes a printer driver 150 to configure color settings of the printer 130. The system may include a plurality of color correction transforms 131 that map color space values sent to or to be sent to the printer 130 into an amount of ink to be printed on a printing medium 140. Color correction transforms may, for example, be implemented as single or multiple dimensional look up tables, mathematical formula, or some combination of these. Color transforms may use a combination of pre-measured data, data automatically collected, or data accumulated in previous manual or automatic calibrations. Color correction transforms 132 and 133 may be implemented within the printer 130 as depicted in FIG. 1. In other embodiments, color correction transforms 132 and 133 may also be implemented elsewhere in the system or in multiple locations. For example, controller system resident software including printer drivers and application software often apply color transforms before printing.

The plurality of color correction transforms 131 may include predefined color correction transforms 132 and custom color correction transforms 133. The plurality of predefined color correction transforms 132 may contain color correction values that map, for example, RGB values of a standard monitor to a plurality of predefined printing device characteristics. For example, the predefined color correction transforms 132 may include: sRGB Display, which matches the RGB color settings of a standard display screen; SWOP Press, which matches U.S. press standards using the Specification for Web Offset Publications; Euroscale Press, which emulates the Euroscale four-color process press mode (printing press standard); and Commercial Press, which emulates a four-color process commercial press mode.

The system preferably includes a display driver 160 to configure color settings of the color monitor 120. The system may further include display color correction transforms (not shown) that map color space values sent to or to be sent to the color monitor 120 into another color space. Preferably, the system also includes application programs to control which of many possible options for display and printing may be used to represent the source image or color pattern 100.

Since color devices behave differently, the plurality of color correction transforms 132 may not provide the most accurate results for the user's application. The plurality of color correction transforms 131 may further include a plurality of custom color correction transforms 133. The plurality of custom color correction transforms 133 may contain user-generated color correction values that map, for example, RGB values of the user's monitor to a printing condition as specified by the user. The custom color correction transforms 133 may be given any identifying name or label either by default, for example, “printer color-to-monitor color match” or by the user and may be saved, for example, in memory in the printer 130 or on a local computer.

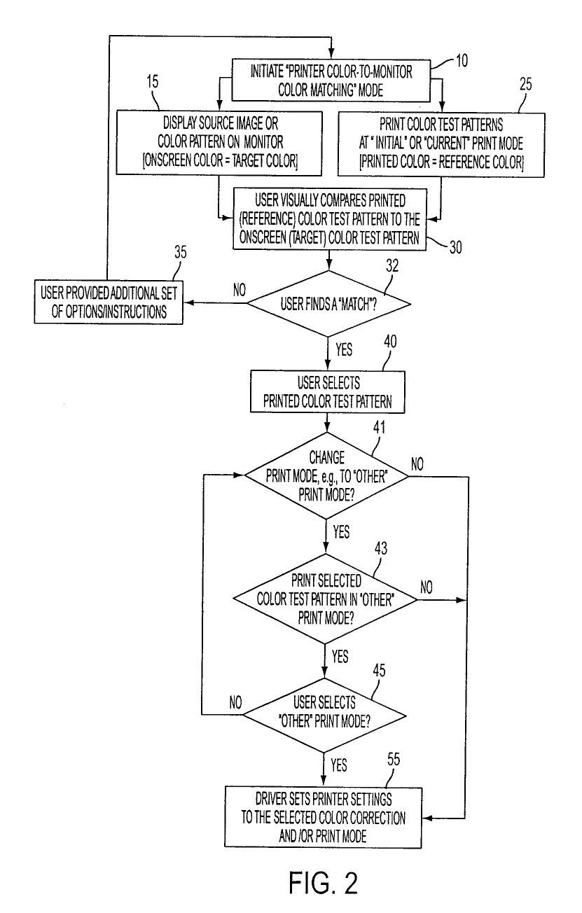

Referring now to FIG. 2, one embodiment of a method for matching colors displayed on a monitor to colors printed on a printer is illustrated. In block 10, a user initiates the printer color-to-monitor color matching process. In one embodiment, the color matching process may be initiated when the printer is initially installed. For example, the user may be prompted to perform the printer color-to-monitor color matching process during the installation of the printer. In other embodiments, the process may be initiated at any time a user desires.

In block 15, a source image or color pattern is displayed on a color monitor (i.e., the target color). In block 25, the same source image or color pattern that is displayed on the monitor may also be printed by the printer. In one embodiment, the printer 130 may be initialized to an “initial” or “default” print mode setting and print a plurality of color test patterns corresponding to the source image or color pattern. In another embodiment, the printer 130 may print the plurality of color test patterns at a “current” print mode setting, i.e., the latest print mode at which the printer was set by the user.

Referring back to FIG. 1, each of the plurality of printed color test patterns may correspond to a color corrected source image or color pattern. In the printer 130, these color transformations may be performed by accessing the color correction transforms 131. In one embodiment, the RGB color space values of the source image or color pattern 100 may be initially mapped to the CMYK color space values of the printer 130, which may then be further mapped through the color correction transforms 131 to further adjust the CMYK values according to a predefined or a user-specified printing condition. These adjusted CMYK values correspond to the actual amount of ink to be transferred on the printing medium 140 to produce the color corrected source image or color pattern.

In another embodiment, the plurality of reference color test patterns may further include a color test pattern corresponding to the source image or color pattern 100 without any color correction being applied. A test pattern without color correction may be desired when the user prefers to work with color settings specified within the user's application. Thus, the application-specified color setting is not altered.

Referring again to FIG. 2, in block 30, the user then makes a visual comparison between the displayed color test pattern and the printed color test patterns. In block 32, the user determines whether one of the reference color test patterns (the reference colors) matches the displayed color test pattern (the target color). Each printed color test pattern may include an identification label to simplify the selection process. Identifying data may include, for example, a calibration test pattern number, the printing device type, and media type on which the test pattern is printed.

The user may select a “best match” between the displayed color test pattern and the printed color test patterns according to a user defined criteria. For example, in one application, the user may be searching for the closest match between the colors. In another application, rather than matching the displayed color test pattern, the user may desire to “enhance” the colors displayed on the monitor instead. For example, if the source color pattern is a photograph, the user may desire to change, rather than match, some or all of the colors in the photograph so as to be more aesthetically pleasing to the user.

In block 35, if none of the printed color test patterns suits the user's particular application, the user is preferably provided on-screen training and/or step-by-step instructions. An on-screen help menu may include a list of optional tasks that the user may perform to overcome specific physical limitations of both of the user's monitor and the printer. For example, the user may be prompted to check whether the monitor is out of adjustment. Calibrating the monitor to operate at particular settings is known in the art and, thus, will not be discussed in further detail.

In another example, the user may be asked whether the user desires to generate a custom color correction table. That is, the user may also generate custom color correction transforms 133 when the standard color correction transforms 132 do not produce the desired printed colors. The user may then re-initiate the printer color-to-monitor color matching process.

In block 40, the user selects the desired printed color test pattern, i.e., a “match” or one that “enhances” the colors in the displayed color test pattern. However, the user may determine that, although the selected reference color test pattern is a “match,” at least one color, for example, is not quite satisfactory for the user's application. In some cases, a problem with matching the monitor color may be resolved by transferring more ink on the printing medium.

In block 41, the user may be given an option to change the print mode for the printer from the “initial” or “current” setting to another print mode. The printer may include a plurality of print modes to optimize print “quality” and speed. Each print mode may be associated with a corresponding ink resolution, i.e., how much ink is transferred to the printing medium. For example, the printer may include a “default” print mode that corresponds to a predetermined ink resolution and allows for a set of colors of be printed. The printer may further include a “photo” print mode that preferably prints at a higher resolution and puts down more ink on the page. The extra ink allows a broader set of colors to be printed, albeit at a slower speed than the “default” print mode.

In block 43, if the user has opted to change print modes, the user may be further given an option to print the selected reference color test pattern in the “other” print mode. The user may then print the selected reference color test pattern in the “other” print mode to perform a second visual comparison and determine if a more preferable color match may be found. In block 45, the user may then select the “other” print mode if a more preferable color match is found or choose another print mode setting, if desired. In another embodiment, some printers may have special internal printing modes that can enable more than one printing mode on a single printed image. In this case, both the print mode and the color correction may then be selected based on a single reference color test pattern, thus further simplifying the color matching process.

In block 55, the printer driver then sets the printer settings to correspond to the color correction and printing mode settings selected by the user. Thus, by selecting a printed color test pattern, the user selects a color correction to apply to the source image or color pattern. By further selecting a print mode, the user selects a print resolution for the color corrected image or color pattern. Therefore, the embodiment of the printer color-to-monitor color matching method provides a simple, user-friendly, and visually-based means for selecting which color correction method and which printing mode to use.

It will be appreciated that various of the above-disclosed and other features and functions, or alternatives thereof, may be desirably combined into many other different systems or applications. Also that various presently unforeseen or unanticipated alternatives, modifications, variations, or improvements therein may be subsequently made by those skilled in the art which are also intended to be encompassed by the following claims.

1. A method for printer color to monitor color matching, comprising:
displaying a target color pattern corresponding to a source color pattern;
printing a plurality of reference color patterns, each of the reference color pattern corresponding to a color corrected source color pattern;
visually comparing the plurality of reference color patterns with the target color pattern; and
determining whether one of the plurality of reference color patterns matches the target color pattern according to a user-defined criteria.

2. The method of claim 1, wherein the source color pattern comprises a plurality of pixels, each pixel associated with values corresponding to a first color space.

3. The method of claim 2, wherein displaying the target color pattern comprises mapping the first color space values of the source color pattern to values corresponding to a second color space associated with a display device.

4. The method of claim 2, wherein printing the plurality of reference color patterns comprises mapping the first color space values of the source color pattern to values corresponding to a third color space associated with a printing device.

5. The method of claim 4, wherein printing the plurality of reference color test patterns further comprises mapping the third color space values associated with the printing device to color space values contained in a plurality of color correction transforms.

6. The method of claim 5, wherein the color space values contained in the plurality of color correction transforms are generated according to predefined printing device characteristics.

7. The method of claim 5, wherein the color space values contained in the plurality of color correction transforms are generated according to user inputs.

8. The method of claim 5, wherein printing the plurality of reference color test patterns comprises printing a sample of inks corresponding to the plurality of color correction transforms.

9. The method of claim 1, further comprising:
selecting a desired reference color test pattern from the plurality of reference color test patterns according to the user-defined criteria.

10. The method of claim 9, further comprising:
selecting a print mode from a plurality of print modes, each mode corresponding to a predetermined amount of ink to be transferred to a print medium.

11. A system, comprising:
a display device to display a source color pattern in a second color space, wherein the source color pattern is represented in a first color space;
a printer to map the first color space values of the source color pattern to values in a third color space associated with the printer and print a plurality of color corrected source patterns, wherein the printer comprises a plurality of print modes, each print mode corresponding to an amount of ink to be transferred to a print medium;
a plurality of color correction transforms to map the third color space values associated with the printer to another set of color space values defined by a selected one of the plurality of color correction transforms; and
a printer driver to configure color settings of the printer according to the selected color correction transform and a selected print mode.

12. The network device of claim 11, wherein each of the plurality of color correction transforms comprises color correction values generated according to predefined device characteristics.

13. The network device of claim 11, wherein each of the plurality of color correction transforms comprises color correction values generated according to user inputs.

14. An article of computer-readable medium containing instructions that, when executed, cause the computer to:
display a target color pattern corresponding to a source color pattern;
print a plurality of reference color patterns, each of the reference color pattern corresponding to a color corrected source color pattern.

15. The article of claim 14, wherein the source color pattern comprises a plurality of pixels, each pixel associated with values corresponding to a first color space.

16. The article of claim 15, wherein the instructions that, when executed, cause the computer to display the target color pattern comprises instructions that, when executed, cause the computer to map the first color space values of the source color pattern to values corresponding to a second color space associated with a display device.

17. The article of claim 16, wherein the instructions that, when executed, cause the computer to print the plurality of reference color patterns comprises instructions that, when executed, cause the computer to map the first color space values of the source color pattern to values corresponding to a third color space associated with a printing device.

18. The article of claim 17, wherein the instructions that, when executed, cause the computer to print the plurality of reference color test patterns further comprises instructions that, when executed, cause the computer to map the third color space values associated with the printing device to color space values contained in a plurality of color correction transforms.

19. The article of claim 18, wherein the instructions that, when executed, cause the computer to print the plurality of reference color test patterns comprise instructions that, when executed, cause the computer to print a sample of inks corresponding to the plurality of color correction transforms.

20. The article of claim 18, wherein the color space values contained in the plurality of color correction transforms are generated according to predefined printing device characteristics.
